(19) United States
(12) Patent Application Publication
(10) Pub. No.: US 2018/0033673 A1
(43) Pub. Date: Feb. 1, 2018

(54) SUBSTRATE SUPPORT WITH IN SITU WAFER ROTATION

(71) Applicant: APPLIED MATERIALS, INC., Santa Clara, CA (US)

(72) Inventors: Srinivas D. Nemani, Sunnyvale, CA (US); Shambhu N. Roy, Fremont, CA (US); Sultan Malik, Sacramento, CA (US); Viachslav Babayan, Sunnyvale, CA (US)

(21) Appl. No.: 15/657,190

(22) Filed: Jul. 23, 2017

Related U.S. Application Data
(60) Provisional application No. 62/366,883, filed on Jul. 26, 2016.

(51) Int. Cl. H01L 21/687; H01L 21/67; H01L 21/02

(52) U.S. Cl. CPC H01L 21/68735; H01L 21/68742; H01L 21/02274; H01L 21/68764; H01L 21/67098

(57) ABSTRACT

Embodiments of methods and apparatus for processing a substrate are provided herein. In some embodiments, a substrate support includes a base having a first support surface designed to support a substrate having a given width; a plurality of arcuate slots formed through the base; a corresponding plurality of lift pins disposed through the arcuate slots, wherein the lift pins are rotationally and vertically movable with respect to the base; and a cover plate disposed on but not coupled to the base to cover the first support surface, wherein the cover plate has a diameter greater than the given width, and wherein the cover plate includes a second support surface designed to support a substrate having the given width.

### CROSS-REFERENCE TO RELATED APPLICATIONS

This application claims benefit of U.S. provisional patent application Ser. No. 62/366,883, filed Jul. 26, 2016, which is herein incorporated by reference in its entirety.

### FIELD

Embodiments of the present disclosure generally relate to substrate processing systems and methods, and more specifically, to methods and apparatus for enhancing process uniformity.

### BACKGROUND

Substrates processed in substrate processing chambers, such as atomic layer deposition (ALD) and plasma enhanced chemical vapor deposition (PECVD) chambers, typically lack uniformity because of azimuthal temperature variation in substrate process chambers. Symmetric chamber designs including a rotating substrate support are often used in such processes in an attempt to enhance uniformity of processing. However, the inventors have observed that due to the lack of relative motion between the substrate support and a substrate disposed thereon, rotatable substrate supports may be ineffective in sufficiently reducing substrate film non-uniformity. For example, the inventors have observed that even substrate supports with relatively high temperature uniformities sometimes produce films with poor uniformity, especially for thick films requiring long process times, or due to variations in substrate placement.

Accordingly, the inventors have provided improved apparatus and methods for processing substrates.

### SUMMARY

Embodiments of methods and apparatus for processing a substrate are provided herein. In some embodiments, a substrate support includes: a base having a first support surface designed to support a substrate having a given width; a plurality of arcuate slots formed through the base; a corresponding plurality of lift pins disposed through the arcuate slots, wherein the lift pins are rotationally and vertically movable with respect to the base; and a cover plate disposed on but not coupled to the base to cover the first support surface, wherein the cover plate has a diameter greater than the given width, and wherein the cover plate includes a second support surface designed to support a substrate having the given width.

In some embodiments, a substrate support includes a base having a first support surface to support a substrate; and a peripheral member having a first side including a second support surface to support the substrate and an opposing second side, wherein the peripheral member is disposed about the base, wherein the first support surface and the second support surface are rotationally movable with respect to each other, and wherein the first support surface and the second support surface are vertically movable with respect to each other sufficient to provide a first vertical configuration wherein the first support surface and the second support surface are coplanar, and a second vertical configuration wherein the second support surface is raised above the first support surface.

In some embodiments, a method of processing a substrate includes performing a process on a substrate of a given width disposed atop a substrate support inside a process chamber, wherein the substrate support has a base having a first support surface covered with a cover plate designed to support the substrate; without removing the substrate from the process chamber, lifting the substrate and the cover plate above the first support surface, and rotating the substrate with respect to the first support surface; and lowering the substrate onto the first support surface and performing the process on the substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a substrate support in accordance with at least some embodiments of the present disclosure.

FIG. 2 depicts a schematic side view of a substrate support in accordance with at least some embodiments of the present disclosure.

FIG. 3 depicts a top view of a substrate support in accordance with at least some embodiments of the present disclosure.

FIG. 4 depicts a top view of a cover plate for a substrate support in accordance with at least some embodiments of the present disclosure.

FIG. 5A depicts a schematic side view of a substrate support including a peripheral member in a first vertical configuration in accordance with at least some embodiments of the present disclosure.

FIG. 5B depicts a schematic side view of the substrate support of FIG. 5A in a second vertical configuration in accordance with at least some embodiments of the present disclosure.

FIGS. 6A, 6B, and 6C depict close up schematic side views of a portion of various embodiments of the substrate support and the peripheral member of FIGS. 5A and 5B.

FIG. 7 depicts a top view of the substrate support of FIGS. 5A and 5B in accordance with at least some embodiments of the present disclosure.

FIG. 8 depicts a top view of a substrate support in accordance with at least some embodiments of the present disclosure.

FIG. 9A depicts a schematic side view of the substrate support of FIG. 8 in a first vertical configuration in accordance with at least some embodiments of the present disclosure.

FIG. 9B depicts a schematic side view of the substrate support of FIG. 8 in a second vertical configuration in accordance with at least some embodiments of the present disclosure.

FIG. 10 is a flowchart illustrating a method of performing a process on a substrate disposed atop a substrate support in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure generally relate to methods and apparatus for processing a substrate. Embodiments of the disclosure include a substrate support having a support surface to support a substrate and configured to rotate with respect to the substrate. The substrate support advantageously provides rotation of a substrate with respect to the substrate support to overcome film non-uniformities due to uneven thermal distribution on the surfaces of the substrate support. Embodiments of the present disclosure further advantageously facilitate rotation of the substrate with respect to the substrate support in situ, i.e., inside the chamber, thus enhancing productivity as compared to transferring the substrate out of the chamber for rotation, and protecting the substrate and films formed thereon from damage due to air exposure and abrupt temperature changes. Although not intended to be limiting of scope, embodiments of the present disclosure may be advantageous in the processing of substrates during thin film processing, fabrication of microelectronic devices, and the like. Exemplary substrates include, for example, semiconductor substrates, glass panels, or the like.

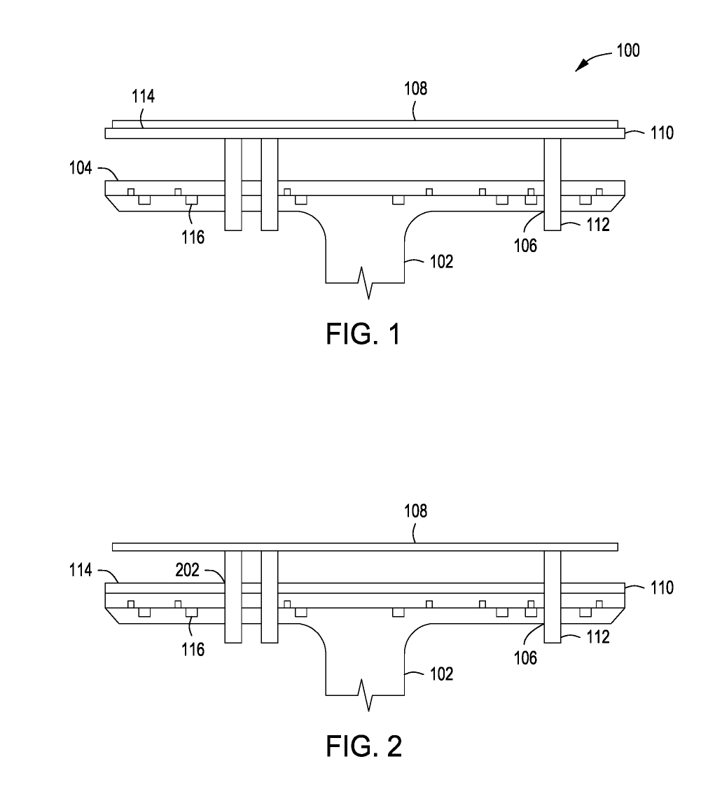

FIG. 1 is a schematic side view of an exemplary substrate support, in accordance with embodiments of the present disclosure, suitable for use in various substrate process chambers. Examples of suitable process chambers and systems that may be suitably modified in accordance with the teachings provided herein include the ENDURA®, CENTURA®, and PRODUCER® processing systems or other suitable processing systems commercially available from Applied Materials, Inc., located in Santa Clara, Calif. Other process chambers and systems (including those from other manufacturers) may also be adapted to benefit from the present disclosure. For example, the process chamber may generally comprise a vacuum or non-vacuum processing volume. For example, the process chamber may be configured to perform various functions including layer deposition including atomic layer deposition (ALD), plasma enhanced chemical vapor deposition (PECVD), physical vapor deposition (PVD), etch, pre-clean, de-gas, annealing, and other substrate processes.

In some embodiments, the substrate support 100 is disposed in the inner volume of a process chamber to facilitate processing of a substrate 108 while keeping the substrate in an isolated atmosphere at all times. In some embodiments, the inner volume may be maintained in a vacuum state (e.g., below atmospheric pressure). The process chamber, and the substrate support 100, may be configured to process and handle substrates of a particular size, including round wafers (e.g., semiconductor wafers) such as 150 mm, 200 mm, 300 mm, 450 mm, or the like.

The substrate support 100 includes a base 102. A top portion of the base 102 includes a first support surface 104 configured to support a substrate 108 of a given width (or diameter), for example, the exemplary diameters recited above. The substrate support 100 is rotatable with respect to the substrate 108 disposed atop the substrate support 100.

In some embodiments, the substrate support 100 may optionally include a first heat transfer apparatus 116 disposed in the base 102, for providing heat to the base 102. The substrate support 100 may also include a temperature monitoring apparatus for monitoring the temperature of the base, and a thermal profile across the base 102. In some embodiments, the first heat transfer apparatus 116 may be a resistive heater disposed in the base 102. Alternatively or in combination, the first heat transfer apparatus 116 may include channels for flowing a heat transfer medium, for example, coolant for cooling the substrate support 100.

In some embodiments, the substrate support 100 may be a vacuum chuck or an electrostatic chuck (ESC). In some embodiments, the substrate support 100 may further include processing apparatus such as electrodes for RF bias, pulsed DC bias, and the like. In other embodiments, the substrate support 100 may optionally include an inlet for flowing in an non-reactive gas, for example, helium for preventing or reducing deposition on the backside of substrate 108 or unwanted deposition on the substrate support 100.

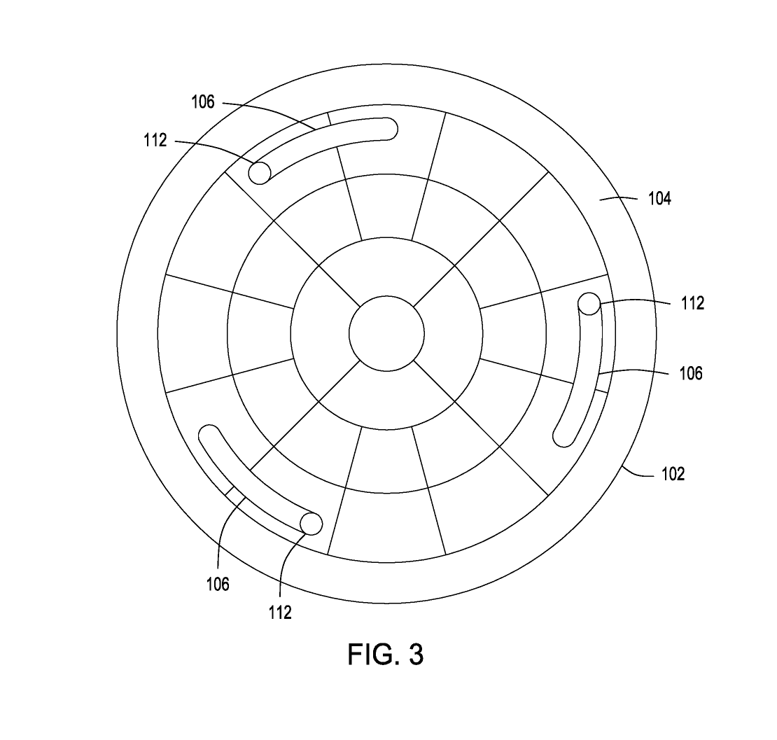

The substrate support 100 further includes a plurality of arcuate slots 106 formed through the base 102. The arcuate slots 106 are more clearly shown in FIG. 3, which depicts a top view of the substrate support 100 without a cover plate (e.g., cover plate 110 discussed in more detail below).

A plurality of lift pins 112 are movably disposed through the arcuate slots 106. The lift pins 112 are rotationally and vertically movable with respect to the base 102, for example, rotationally along the arcuate slots 106, and vertically through the arcuate slots 106. As used herein, rotational movement of the lift pins 112 with respect to the base 102 means that the lift pins 112 rotate synchronously (e.g., all at the same time) along the respective arcuate slots 106 and about a central axis of the first support surface 104, rather than the respective central axes of the lift pins 112. In some embodiments, the substrate support 100 is non-rotatable and the lift pins 112 are rotatable. In some embodiments, the substrate support 100 is rotatable and the lift pins 112 are non-rotatable. In some embodiments, both the substrate support 100 and the lift pins 112 are rotatable.

In some embodiments, the lift pins 112 may be rotatable along the arcuate slots 106 through a range of angles from a minimum angle of rotation of more than 0 degrees to a maximum angle of rotation. For example, in some embodiments, the minimum angle of rotation may be in a range from about 0 degrees to about 5 degrees, for example, 5 degrees, and the maximum angle of rotation may be in a range from about 90 degrees to about 110 degrees, for example 90 degrees. In other words, the lift pins can rotate along the arcuate slots up to about 110 degrees, or up to about 90 degrees, or from about 5 degrees to about 110 degrees, or from about 5 degrees to about 90 degrees. In accordance with the exemplary embodiments of the present disclosure, the maximum angle of rotation may depend on the number of lift pins 112. For example, the maximum angle of rotation in an embodiment having a number of n lift pins may be according to the relationship ((360 degrees/n)−10 degrees)). Accordingly, in the exemplary embodiment depicted in FIGS. 1 and 2, where the number of lift pins is 3, the maximum angle of rotation is 110 degrees.

In some embodiments, a cover plate 110 is disposed on the base 102 to cover the first support surface 104. The cover plate 110 includes a second support surface 114 designed to support a substrate 108 having a given width. The cover plate 110 has a diameter equal to or greater than the given width of the substrate 108. For example, the diameter of the cover plate 110 may be equal to the given width of the substrate 108 or greater than the given width of the substrate 108. In some embodiments, for example, in a process chamber configured to process one substrate at a time, the diameter of the cover plate 110 may be up to about 50 mm greater than the given width of the substrate 108. In other embodiments, for example in a configuration for processing multiple substrates, for example, 6 wafers, the wafers may have a width of about 300 mm and the cover plate may have a diameter of up to 1000 mm. The cover plate 110 has a suitable thickness for handling and to prevent bowing or fracturing during handling and processing of the cover plate 110 and a substrate 108 disposed on the cover plate 110. In some embodiments, the cover plate has a thickness of about 5 to about 50 mm. In some embodiments, either or both of the second support surface 114 of the cover plate 110 and an opposing bottom surface of the cover plate 110 are planar. In some embodiments, the second support surface 114 and the opposing bottom surface are coplanar. In some embodiments, the second support surface 114 can include a recess to minimize contact with the backside of a substrate disposed on the cover plate 110. Alternatively or in combination, the second support surface 114 can include protruding substrate locating guides or pins.

The cover plate 110 may have a high thermal conductivity, such as from about 5 W/m·K to about 500 W/m·K. In some embodiments, the cover plate 110 may have a thermal conductivity that is greater than or equal to that of the base 102. The cover plate 110 may be fabricated from one or more suitable process-compatible materials such as copper, aluminum, stainless steel, ceramic (such as alumina, aluminum nitride, or the like), and the like. The thermal conductivity of the cover plate advantageously facilitates diffusion of heat transferred from the substrate support and smoothing of the resultant thermal profile on the cover plate (and therefore, on the substrate).

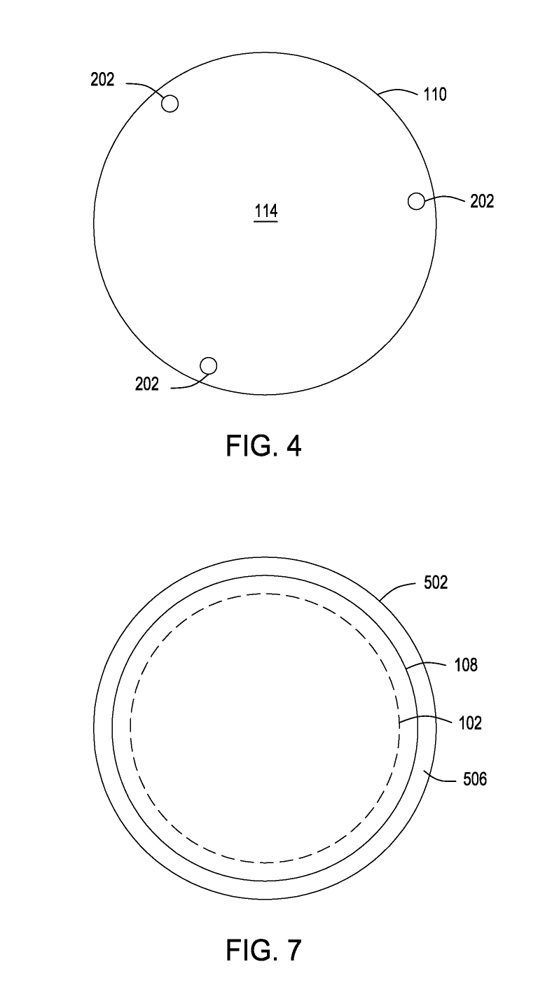

As depicted in FIGS. 2 and 4, the cover plate 110 further comprises a plurality of holes 202 that are located in positions corresponding to respective positions of the plurality of lift pins 112. Depending upon the angular orientation of the cover plate 110 with respect to the base 102 (and thus the plurality of lift pins 112), the lift pins 112 may engage and lift the cover plate 110 above the first support surface 104 (e.g., when the lift pins 112 are not aligned with the holes 202) or the lift pins 112 may pass through the cover plate 110 to lift the substrate 108 above the first support surface 104 and the second support surface 114 of the cover plate 110 (e.g., when the lift pins 112 are aligned with the holes 202).

For example, in some embodiments, the substrate 108 may be transferred onto or off of the second support surface 114 by a robotic arm or other suitable substrate transfer apparatus by aligning the lift pins 112 and the holes 202 and extending the lift pins 112 through the cover plate 110 to lift only the substrate 108 and not the cover plate 110. Specifically, during transfer of the substrate 108, the cover plate 110 may rest on the first support surface 104 and the plurality of holes 202 provide access for the lift pins 112 to move upwardly through the holes 202 and lift the substrate 108 off the second support surface 114. The lift pins 112 are configured to extend sufficiently to lift the substrate 108 off the second support surface 114 and provide room for a robotic arm or other suitable substrate transfer apparatus to remove the substrate 108 from the substrate support 100. The lift pins 112 are also configured to extend through the holes 202 to receive a substrate 108 while the cover plate 110 rests on the first support surface 104.

Alternatively, the substrate 108 and the cover plate 110 may be transferred onto or off of the first support surface 104 together. In some embodiments the cover plate 110 may have no holes, for example, wherein the substrate 108 and the cover plate 110 are always transferred onto or off of the first support surface 104 together.

Alternatively, in some embodiments the second support surface 114 can include arcuate slots similar to the arcuate slots 106 disclosed above with respect to the substrate support. The arcuate slots can vary in the same manner as described above with respect to the arcuate slots 106. In embodiments where the second support surface has arcuate slots, the arcuate slots can align with the arcuate slots 106 in the base 102 to facilitate rotation of the substrate with respect to both the cover plate and the substrate support.

The lift pins 112 are vertically movable from a retracted position to an extended position. The extended position of the lift pins 112 may be a singular extended position or may include at least a minimum vertical position and a maximum vertical position. The minimum vertical position and the maximum vertical position may, for example, be measured relative to the vertical position of the first support surface 104. The minimum vertical position is configured to allow rotation of the substrate 108 with respect to the substrate support. For example, the minimum vertical position may be between about 5 mm to about 10 mm. The maximum vertical position is configured to facilitate transferring the substrate 108 onto and off of the substrate support 100. For example, the maximum height may be selected based on the configuration of a robotic arm or other suitable substrate transfer apparatus for transferring the substrate 108 onto or off the second support surface 114. For example, the maximum vertical position may be between about 25 mm to about 50 mm. In some embodiments, the lift pins 112 may be vertically movable between more than two extended vertical positions, for example, three or four vertical positions.

In operation according to some embodiments, when the cover plate 110 is resting on the first support surface 104, a process is performed on the substrate 108 disposed on the second support surface 114 of the cover plate 110. Without removing the substrate from the process chamber, the cover plate 110 and a substrate 108 disposed on the second support surface 114 of the cover plate 110 are lifted together by the lift pins 112 to a vertical position above the first support surface 104. The lift pins 112 lift the cover plate 110 together with the substrate 108 when the holes 202 and the lift pins 112 are not aligned.

When the cover plate 110 and substrate 108 have been lifted from the first support surface 104, the lift pins 112 rotate azimuthally along the arcuate slots 106 with respect to the first support surface 104. The cover plate 110 and the substrate 108 supported by the lift pins 112 are similarly rotated with respect to the first support surface 104. When rotation is complete, the lift pins 112 may be retracted to lower the cover plate 110 and substrate 108 onto the first support surface 104 and the processing of substrate 108 may be resumed. In some embodiments, substrate rotation and processing may be performed concurrently.

The angle of rotation of the lift pins 112 along the arcuate slots 106, as discussed above, may be selected based on a thermal profile across the base 102.

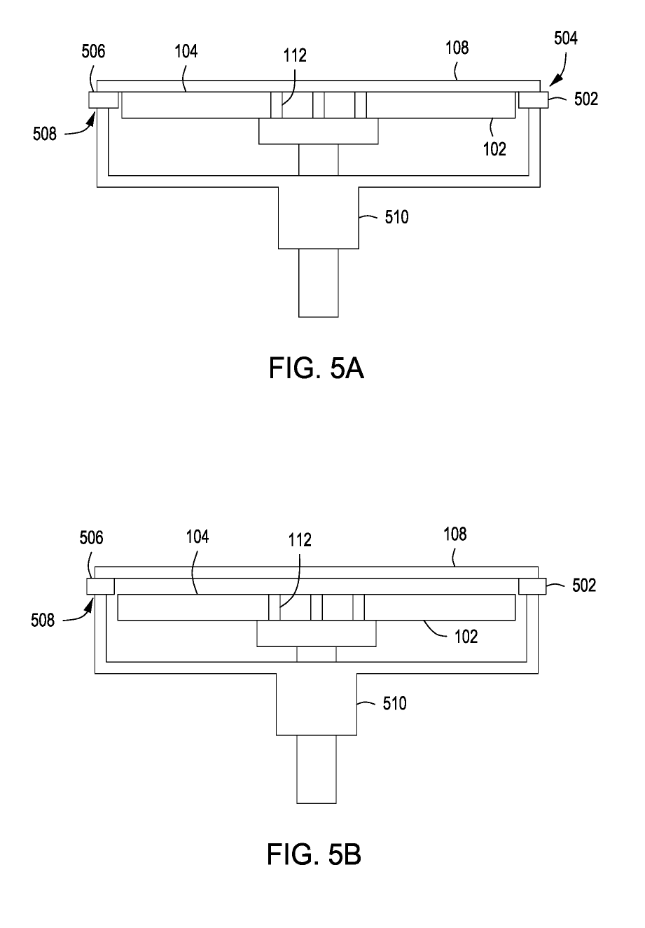

FIGS. 5A and 5B depict the substrate support 100 in accordance with embodiments of the present disclosure where the substrate support 100 further includes a peripheral member 502 having a first side 504 including a second support surface 506 to support the substrate 108 and an opposing second side 508, wherein the peripheral member 502 is disposed about the base 102, wherein the first support surface 104 and the second support surface 506 are rotationally movable with respect to each other, and wherein the first support surface 104 and the second support surface 506 are vertically movable with respect to each other sufficient to provide a first vertical configuration wherein the first support surface 104 and the second support surface 506 are coplanar, and a second vertical configuration wherein the second support surface 506 is raised above the first support surface 104.

As depicted in FIGS. 5A and 5B, in embodiments including the peripheral member 502, the peripheral member 502 is vertically and rotationally movable with respect to the base 102. Such vertical and rotational movement may be achieved through control of the position of the peripheral member 502, the base 102 or both the peripheral member 502 and the base 102. For example, in some embodiments, the substrate support 100 may further include a vertical and rotational actuator 510. The vertical and rotational actuator 510 may be coupled to the peripheral member 502 to provide rotational and vertical motion to the peripheral member 502. The vertical and rotational actuator 510 may include separate actuators for controlling the vertical movement and the rotational movement. Alternatively, or in combination, various combinations of actuators, motors, belts, gears, or the like may be used to control the vertical position of either of the peripheral member 502 or the base 102. In addition, various combinations of actuators, motors, belts, gears, or the like may be used to control the rotational position of either of the peripheral member 502 or the base 102. The relative rotational motion and the relative vertical motion may be provided to different ones of the peripheral member 502 and the base 102. For example, the peripheral member may be vertically fixed with respect to the process chamber and rotationally movable (or rotationally fixed and vertically movable), while the base 102 is vertically movable with respect to the process chamber and rotationally fixed (or rotationally movable and vertically fixed), such that one component provides the relative vertical motion and the other component provides the relative rotational movement. Alternatively, a single one of the peripheral member 502 and the base 102 can provide both of the vertical and rotational movement or both the peripheral member 502 and the base 102 can each provide vertical and rotational movement.

In some embodiments including the peripheral member 502, the substrate support 100 may optionally include lift pins 112 for lifting the substrate 108, as depicted in FIGS. 5A and 5B. The lift pins 112 are vertically movable with respect to the base 102. As used herein, vertical movement of the lift pins 112 with respect to the base 102 means that at least one of the base 102 or the lift pins 112 are vertically movable with respect to each other sufficient to dispose the base 102 and lift pins 112 in a first vertical configuration where tops of the lift pins 112 are disposed above the first support surface of the base 102, and in a second vertical configuration wherein tops of the lift pins 112 are disposed even with or below the first support surface of the base 102.

In the first vertical configuration depicted in FIG. 5A, first support surface 104 and the second support surface 506 are coplanar. In the second vertical configuration (depicted in FIG. 5B) the second support surface 506 is raised above the first support surface 104. The second vertical position also provides access to a substrate transfer apparatus, such as a robotic arm or the like to transfer the substrate 108 onto and off the peripheral member 502, or for transfer of the substrate 108 into and out of the process chamber.

In some embodiments including the peripheral member 502, the first heat transfer apparatus 116 may further provide heat to the peripheral member 502. In other embodiments including the peripheral member 502, a temperature monitoring apparatus may be provided for monitoring the temperature and thermal profiles across both the base 102 and the peripheral member 502. The first heat transfer apparatus 116 is not shown in FIGS. 5A and 5B for clarity.

In some embodiments, the peripheral member 502 has a thermal conductivity that is approximately equal to that of the base 102. In some embodiments, the peripheral member 502 has a thermal conductivity of about 5 W/m·K to about 500 W/m·K. In some embodiments, the peripheral member 502 may comprise at least one of silicon or silicon carbide. In other embodiments, in the first vertical configuration, the peripheral member 502 may rest on an adjacent surface abutting the perimeter of the base 102. The adjacent surface abutting the perimeter of the base 102 may be fabricated from the same material as the base, for example, silicon or silicon carbide.

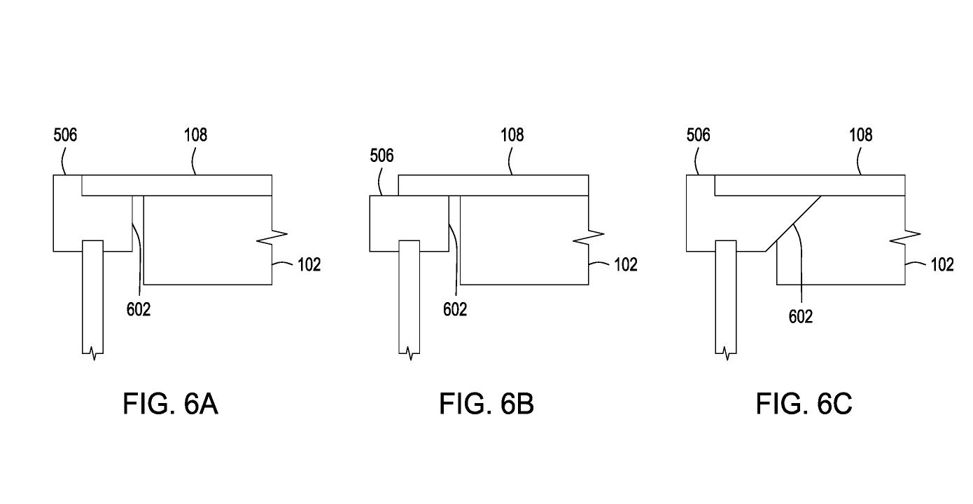

In some embodiments, the peripheral member 502 may include a feature for receiving and supporting a substrate. The feature may be, for example, a lip designed to ensure that in the first vertical position, the second support surface 506 and the principal surface of the substrate 108 are coplanar. In some embodiments, for example, as depicted in FIG. 6A, the lip may be formed by a cut-out step disposed in the first side 504 and joining the remainder of the second support surface 506 to an interior edge 602 of the peripheral member 502. In other embodiments of the first vertical configuration, for example, as depicted in FIG. 6B, a substantial portion of the second support surface 506 may be flat and coplanar with the first support surface 104 such that the principal surface of the substrate 108 is disposed above both the first support surface 104 and the second support surface 506. In other embodiments of the first vertical configuration, the outer edge of the base 102 engages and mates with the interior edge 602. FIG. 6C illustrates a non-limiting example of an embodiment wherein the outer edge of the base 102 is configured to engage and mate with the interior edge 602.

In some embodiments, the peripheral member 502 may be a hoop, or annular member. The hoop can be any closed shape having a surface surrounding the inner perimeter of the shape. Non-limiting examples of the shapes of the hoop include a circle, a quadrilateral, or a hexagon. FIG. 7 is an illustration of an embodiment wherein the peripheral member 502 is a circular hoop. FIG. 7 depicts a top view of the peripheral member 502 surrounding the base 102 having a substrate 108 disposed on the second support surface 506, and over the base 102. The dotted inner circle in FIG. 7 depicts the base 102 in an exemplary embodiment where the diameter of the substrate 108 is larger than the diameter of the base 102 and less than the diameter of the peripheral member 502.

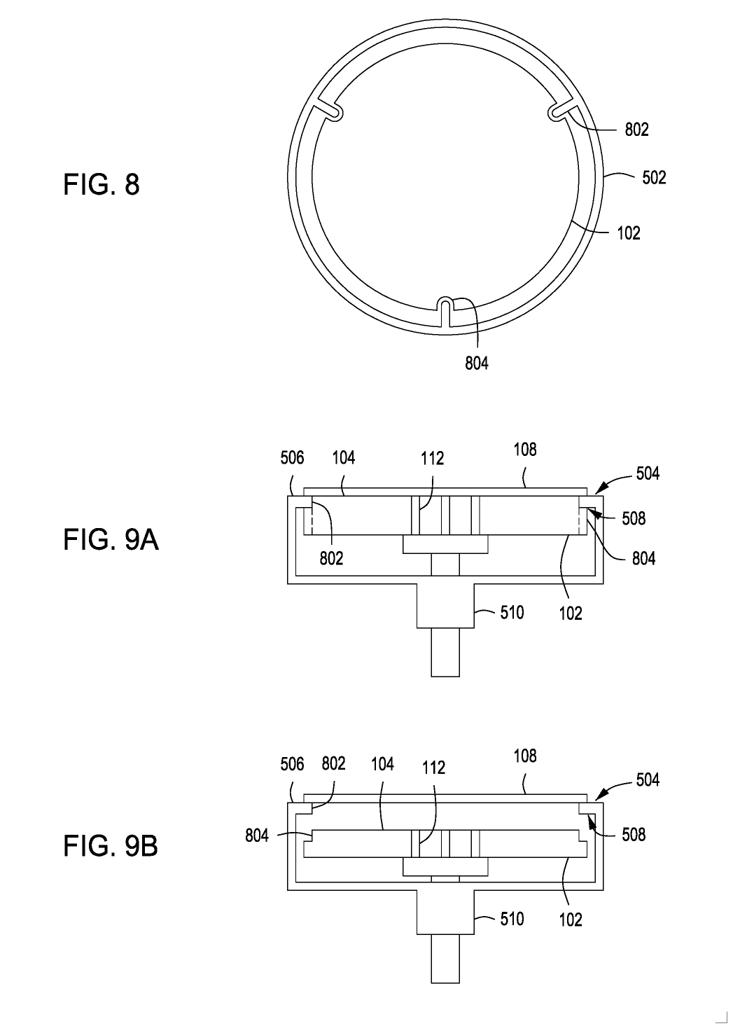

In some embodiments including the peripheral member 502, the peripheral member 502 may include a plurality of fingers 802 that extend radially inward from the peripheral member 502. A plurality of slots 804 are formed in the base 102, as depicted in the top view of the substrate support of FIG. 8. The second support surface 506 of the peripheral member is disposed at least partially along the plurality of fingers 802.

The number of the plurality of slots 804 may be the same or more than the number of the plurality of fingers 802. Thus, in some embodiments of the first vertical configuration (as recited above) each one of the plurality of fingers may be configured to be disposed in any one of the plurality of slots in order to maximize the number of possible angular positions where each one of the plurality of fingers may be disposed.

The plurality of fingers 802 extend radially inward from a position outside of the perimeter of the first support surface 104 of the base 102 to a position within the perimeter of the first support surface 104 such that each one of fingers 802 can be selectively disposed inside the slots 804 depending on the position of the peripheral member 502 with respect to the base 102.

For example, as illustrated in FIG. 9A and in accordance with the first vertical configuration discussed above, the plurality fingers 802 may be substantially disposed inside the slots 804 so that the second support surface 506 and the first support surface 104 are coplanar.

FIG. 9B depicts a side view of an exemplary second vertical configuration in accordance with the substrate support of FIG. 8. As depicted in FIG. 9B, the plurality of fingers 802 are above the slots 804, such that the peripheral member 502 is in the second vertical configuration.

In operation, according to some embodiments including the peripheral member 502, when the peripheral member 502 is in the first vertical configuration (e.g., as depicted in FIGS. 5A and 9A), a process is performed on the substrate 108. Without removing the substrate from the process chamber, the substrate 108 disposed on the second support surface 506 and the peripheral member 502 are lifted together by a vertical motion of the vertical and rotational actuator 510 coupled to the peripheral member 502. The peripheral member 502 and the substrate 108 are lifted above the first support surface 104 to a vertical position corresponding to the second vertical configuration. In the second vertical configuration (e.g., as depicted in FIGS. 5B and 9B), the peripheral member 502 having the substrate 108 supported thereon is rotated with respect to the first support surface 104 by the rotational motion of the vertical and rotational actuator 510. When rotation is complete, the peripheral member 502 and the substrate 108 are lowered by the vertical and rotational actuator 510 onto the first support surface 104. When the first support surface 104 and the second support surface 506 are coplanar and substrate processing may be resumed.

In some embodiments, substrate rotation and processing may be performed concurrently. In other embodiments, substrate processing and rotation may be performed sequentially. The amount of rotation of the peripheral member 502 may be selected based on at least one of thermal profile across the base 102 or the thermal profile across the peripheral member 502.

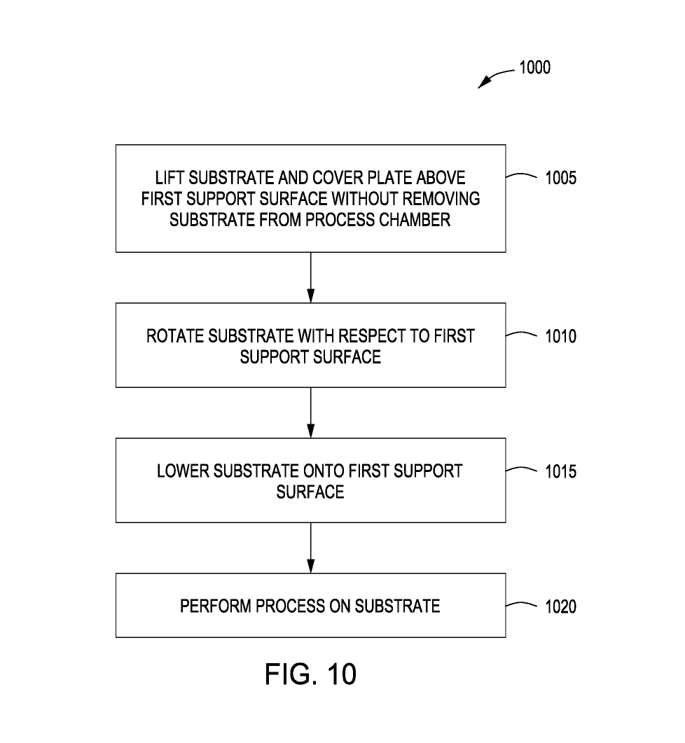

FIG. 10 is a flowchart illustrating a method 1000 of processing a substrate placed on substrate supports of the present disclosure during processing. At 1005, without removing the substrate from the process chamber, the substrate and the cover plate are lifted above the first support surface. At 1010, the substrate is rotated with respect to the first support surface. At 1015, the substrate is lowered onto the first support surface. At 1020, a process is performed on the substrate. Thus, the substrate may be rotated to improve uniformity, without compromising film quality due to performing substrate rotation outside of the process chamber.

Thus, embodiments of substrate support apparatus and methods of using the same to reduce or eliminate substrate film non-uniformities due to, for example, variations between pedestals or variations in wafer-to-wafer placement and methods of using the same have been provided.

While the foregoing is directed to embodiments of the present disclosure, other and further embodiments of the disclosure may be devised without departing from the basic scope thereof.

1. A substrate support, comprising:
a base having a first support surface designed to support a substrate having a given width;
a plurality of arcuate slots formed through the base;
a corresponding plurality of lift pins disposed through the arcuate slots, wherein the lift pins are rotationally and vertically movable with respect to the base; and
a cover plate disposed on but not coupled to the base to cover the first support surface, wherein the cover plate has a diameter greater than the given width, and wherein the cover plate includes a second support surface designed to support a substrate having the given width.

2. The substrate support of claim 1, wherein the cover plate further comprises a plurality of holes configured to be aligned to the plurality of lift pins for transfer of the substrate onto or off of the second support surface.

3. The substrate of claim 1, wherein the cover plate has a thermal conductivity that is greater than or equal to the thermal conductivity of the base.

4. The substrate support of claim 3, further comprising:
a first heat transfer apparatus for providing heat to the base.

5. The substrate support of claim 4, further comprising:
a temperature monitoring apparatus for monitoring the temperature of the base, and a thermal profile across the base.

6. The substrate support of claim 4, wherein the first heat transfer apparatus is a resistive heater disposed in the base.

7. A substrate support, comprising:
a base having a first support surface to support a substrate; and
a peripheral member having a first side including a second support surface to support the substrate and an opposing second side, wherein the peripheral member is disposed about the base, wherein the first support surface and the second support surface are rotationally movable with respect to each other, and wherein the first support surface and the second support surface are vertically movable with respect to each other sufficient to provide a first vertical configuration wherein the first support surface and the second support surface are coplanar, and a second vertical configuration wherein the second support surface is raised above the first support surface.

8. The substrate of claim 7, wherein the peripheral member has a thermal conductivity that is approximately equal to the thermal conductivity of the base.

9. The substrate support of claim 7, wherein the peripheral member comprises silicon or silicon carbide.

10. The substrate support of claim 7, wherein the peripheral member rests on an adjacent surface of the base when in the first vertical configuration.

11. The substrate support of claim 7, wherein an outer edge of the base extends radially outward in a direction moving away from the first support surface, and wherein an interior edge of the peripheral member is configured to mate with the outer edge of the first support surface.

12. The substrate support of claim 7, wherein the peripheral member further comprises a lip for receiving and supporting the substrate.

13. The substrate support of claim 12, wherein the lip and the base are made of the same material.

14. The substrate support of claim 7, further comprising:
a first heat transfer apparatus for providing heat to the base; and
a temperature monitoring apparatus for monitoring the temperature of the base, and a thermal profile across the base.

15. The substrate support of claim 7, further comprising:
a plurality of lift pins disposed through the base to selectively raise or lower a substrate with respect to the first support surface.

16. The substrate support of claim 7, wherein the peripheral member is a hoop.

17. The substrate support of claim 7, further comprising:
slots formed in the first support surface, wherein the peripheral member comprises a plurality of fingers that extend radially inward from a position outside of the perimeter of the first support surface to a position within the perimeter of the first support surface such that respective fingers can be selectively disposed inside the slots depending upon the position of the peripheral member with respect to the base, wherein the first side of the peripheral member is disposed at least partially along the plurality of fingers.

18. The substrate support of claim 7, further comprising:
a plurality of slots formed in the first support surface, wherein the peripheral member comprises a plurality of fingers that extend radially inward from a position outside of the perimeter of the first support surface to a position within the perimeter of the first support surface such that respective fingers can be selectively disposed inside the slots depending upon the position of the peripheral member with respect to the base, wherein the second support surface is disposed at least partially along the plurality of fingers.

19. The substrate support of claim 18, wherein the number of the plurality of slots is the same or more than the number of the plurality of fingers, and wherein each one of the plurality of fingers is configured to be disposed in any one of the plurality of slots.

20. A method of processing a substrate, comprising:
performing a process on a substrate of a given width disposed atop a substrate support inside a process chamber, wherein the substrate support has a base having a first support surface covered with a cover plate designed to support the substrate;
without removing the substrate from the process chamber, lifting the substrate and the cover plate above the first support surface, and rotating the substrate with respect to the first support surface; and
lowering the substrate onto the first support surface and performing the process on the substrate.
